(19) United States
(12) Patent Application Publication
(10) Pub. No.: US 2010/0117106 A1
(43) Pub. Date: May 13, 2010

(54) LED WITH LIGHT-CONVERSION LAYER

(75) Inventor: TROY A. TROTTIER, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: LedEngin, Inc., Santa Clara, CA (US)

(21) Appl. No.: 12/267,512

(22) Filed: Nov. 7, 2008

(51) Int. Cl. H01L 33/00

(52) U.S. Cl. 257/98; 438/22; 257/E33.061

(57) ABSTRACT

A lighting apparatus includes a light-emitting diode (LED). A light-conversion layer having multiple non-overlapping regions overlies the light-emitting diode. The light-conversion layer includes at least one first region and at least one second region. In the lighting apparatus, the light-emitting diode is configured to emit light of a first color, the at least one first region is substantially transparent to light of the first color, and the at least one second region converts light of the first color to light of a second color. In an embodiment, the light-conversion layer is configured such that the lighting apparatus provides substantially uniform light of a third color. In some embodiments, the second region includes a phosphor-containing material, and the first region includes silicone or epoxy. In an example, the lighting apparatus uses a blue LED in conjunction with a yellow phosphor material to produce white light.

### CROSS-REFERENCES TO RELATED APPLICATIONS

The application is related to U.S. patent application Ser. No. 11/036,559, filed on Jan. 13, 2005 and entitled “Light Emitting Device with a Thermal Insulating and Refractive Index Matching Material,” which is commonly owned and incorporated by reference herein.

### FIELD OF THE INVENTION

The present invention relates generally to lighting apparatus and more particularly to methods and apparatus for providing enhanced brightness in light sources based on light-emitting diodes (LEDs).

### BACKGROUND OF THE INVENTION

A light-emitting diode (LED) is a semiconductor device that produces light when an electric current is passed therethrough. LEDs have many advantages over conventional lighting sources, including compact size, low weight, longer life time, high vibration resistance, and higher reliability. In addition to having widespread applications for electronic products as indicator lights, LEDs also have become an important alternative light source for various applications where incandescent and fluorescent lamps have traditionally predominated.

Additionally, wider applicability of LEDs has been made possible through the use of phosphors in conjunction with LEDs. A phosphor is a luminescent material that, when excited by a light of a certain wavelength, produces a light at a different wavelength, thus modifying the output light of the LED. Accordingly, where a particular color is desired and that color cannot be produced by available LEDs cost effectively, phosphors can be used as light “converters” to alter the color of the light produced by an available LED to the desired color.

For example, phosphors are now used with monochromatic LEDs to produce white light. Using phosphors to convert the light produced by an LED to white light has proven to be a viable alternative to conventional white light sources, including incandescent light sources and the direct red-green-blue (RGB) LED methods in which multiple monochromatic LEDs are combined in a RGB scheme to produce white light.

In a typical LED-based white light producing device, a monochromatic LED is encapsulated by a transparent material containing appropriate compensatory phosphors. The wavelength(s) of the light emitted from the compensatory phosphor is compensatory to the wavelength of the light emitted by the LED such that the wavelengths from the LED and the compensatory phosphor mix together to produce white light. For instance, a blue LED-based white light source produces white light by using a blue light LED and a phosphor that emits a yellowish light when excited by the blue light emitted from the LED. In these devices the amount of the phosphor in the transparent material is carefully controlled such that only a fraction of the blue light is absorbed by the phosphor while the remainder passes unabsorbed. The yellowish light and the unabsorbed blue light mix to produce white light.

Another exemplary scheme uses an LED that produces light outside of the visible spectrum, such as ultraviolet (UV) light, together with a mixture of phosphors capable of producing either red, green, or blue light when excited. In this scheme, the light emitted by the LED only serves to excite the phosphors and does not contribute to the final color balance.

As demand for better lighting devices continues to increase, it would be desirable to provide cost-effective LED-based lighting sources having improved efficiency and brightness.

### BRIEF SUMMARY OF THE INVENTION

Even though conventional LED-based white light sources have found wide application, they suffer from many limitations. One common problem is that conventional LED-based white light sources often do not provide sufficient brightness. As described in more detail below, it is difficult to optimize LED-based lighting devices such that the light is both maximally bright and truly white. While brightness can be increased by increasing operating voltage, this increases operating costs and thermal management requirements.

Accordingly, it would be desirable to provide cost-effective LED-based lighting sources having improved efficiency and brightness. Such improvement will allow for devices with smaller packages and higher luminosities, which are critical for many light source applications.

The present invention relates generally to lighting apparatus and more particularly to methods and apparatus for providing enhanced brightness in LED-based lighting devices. In embodiments of the invention, various methods are provided for forming a light-conversion layer that allow for separate optimization of light conversion efficiency and proportion of light components having different colors. The light-conversion layer can includes certain regions that are substantially free of any wave-shifting material and other regions that contain wave-shifting material. Additionally, the light-conversion layer can also include multiple regions that contain different wave-shifting materials. Merely by way of example, such a light-conversion layer has been applied to a lighting apparatus with a blue LED to produce white light with improved brightness compared to conventional devices.

In a specific embodiment for producing substantially uniform white light, the light-conversion layer includes two types of non-overlapping regions, where regions of the first type contain yellow phosphor for converting blue light to yellow light and regions of the second type are substantially transparent to blue light. The thickness of the light-conversion layer is selected for maximum yellow light conversion efficiency, and the pattern of the two types of regions in the light-conversion layer is designed for providing the desired ratio and uniformity of yellow and blue light, respectively, for producing substantially uniform white light.

In another embodiment, the light-conversion layer can have regions of green phosphor, regions of red phosphor, and clear regions that are free of phosphor material; such a layer can be used with various LEDs to produce colored light. Of course, there can be other variations and modifications. For example, the light-conversion layer can be an n-region structure, with n denoting the number of different regions, and different regions can contain different phosphors or other wave-shifting materials, or no wave-shifting materials as desired.

In various embodiments, the present invention provides methods for forming light-conversion layers as well as lighting apparatus having enhanced brightness. In one example, a method for forming a light-conversion layer includes forming a phosphor-containing layer and then forming holes in the phosphor-containing layer. In another example, the method includes forming holes in a transparent base material and then filling the holes with a phosphor-containing material. When used with a blue LED, the phosphor regions of the light-conversion layer convert at least some of the blue light to yellow light, whereas the transparent regions or holes allow blue light to pass through.

Even though the invention has been applied to LED-based white light sources, it would be recognized that the invention has a much broader range of applicability. For example, various combinations of phosphor (or other wave-shifting material) and light source having different colors can be used to produce a substantially uniform light of a desired color.

According to an embodiment of the present invention, a lighting apparatus includes a light-emitting diode and a light-conversion layer having multiple-regions overlying the light-emitting diode. In some embodiments, the multiple regions are non-overlapping. The light-conversion layer includes at least one first region and at least one second region. In the lighting apparatus, the light-emitting diode is configured to emit light of a first color, the at least one first region is substantially transparent to light of the first color, and the at least one second region converts light of the first color to light of a second color. In an embodiment, the light-conversion layer is configured such that the lighting apparatus provides substantially uniform light of a third color. In a specific embodiment, the second region includes a phosphor-containing material, and the first region includes silicone or epoxy. In some embodiments, the lighting apparatus is adapted for producing white light, i.e., the third color is white. In white light applications, the first color can be blue while the second color can be yellow. In this example, a blue LED is used in conjunction with a yellow phosphor material to produce white light.

According to another embodiment of the present invention, a lighting apparatus includes a blue light-emitting diode and a light-conversion layer overlying the light-emitting diode. The light-conversion layer has a plurality of non-overlapping regions including one or more wave-shifting regions and one or more non-wave-shifting regions. The light-conversion layer is configured such that the lighting apparatus provides substantially uniform white light. The light-conversion layer can be in physical contact with the light-emitting diode, or spaced apart from the light-emitting diode. Alternatively, the light-conversion layer can be in direct contact with a lens in a top portion of the lighting apparatus. In some embodiments, the thickness of the light-conversion layer is selected to maximize yellow light output. Furthermore, the pattern of wave-shifting regions and non-wave-shifting regions can be designed for providing the desired ratio and distribution of yellow and blue light to produce substantially uniform white light.

In yet another embodiment, the present invention provides a method for making a lighting apparatus. The method includes providing a light-emitting diode. The method also includes forming a light-conversion layer overlying the light-emitting diode. The light-conversion layer includes one or more wave-shifting regions and one or more non-wave-shifting regions. For example, if the light-emitting diode is configured to emit light of a first color, the non-wave-shifting regions are substantially transparent to light of the first color, and the wave-shifting regions convert light of the first color to light of a second color. In an embodiment, the light-conversion layer is configured to provide substantially uniform light of a third color. In a specific embodiment, a lens is added to the lighting apparatus, and the light-conversion layer is formed on a back surface of the lens. Alternatively, the light-conversion layer can be formed directly on a top surface of the light-emitting diode.

In the above method, the light-conversion layer can be made by different processes. In some embodiments, the LED can be disposed on a flat substrate. In other embodiments, the substrate has a recess, and the LED can be disposed in the recess in the substrate. In a specific embodiment, the light-conversion layer is formed by first filling the recess with a base material that is substantially transparent to the light emitted from the light-emitting diode, then curing the base material. Subsequently, one or more voids are formed in the base material, and the voids are filled with a wave-shifting material. The base material may include, e.g., a gel of silicone or an epoxy material. In another embodiment, the light-conversion layer is formed by first forming a layer or plate of a wave-shifting material, then forming one or more holes in the layer or plate. The holes can be left empty or filled with a base material that is substantially transparent to the light emitted by the light-emitting diode. In this embodiment, the thickness of the plate can be selected for providing a predetermined light-conversion efficiency of the wave-shifting material.

In yet another embodiment, the present invention provides a light converting device. The light converting device includes a light-conversion layer having a plurality of non-overlapping regions including at least one wave-shifting region and at least one non-wave-shifting region. The wave-shifting region converts light of a first color to light of a second color and the non-wave-shifting region is substantially transparent to light of the first color. In a specific embodiment, the light-conversion layer is configured to provide substantially uniform light of a predetermined color when combined with a light source having a different color.

In another embodiment, the present invention provides a light conversion device that includes a light conversion layer having a plurality of non overlapping regions including at least one region of a first type and at least one region of a second type. The at least one region of the first type is configured to convert incident light of a first color to light of a second color, and the at least one region of the second type is configured to convert incident light of the first color to light of a third color that is different from the second color.

Various additional objects, features, and advantages of the present invention can be more fully appreciated with reference to the detailed description and accompanying drawings that follow.

### BRIEF DESCRIPTION OF THE DRAWINGS

FIG. 1 is a simplified diagram of a conventional LED-based light emitting device;

FIG. 2 is a simplified diagram of another conventional LED-based light emitting device;

FIG. 3A is a simplified graph illustrating intensity of blue light versus thickness of a phosphor layer;

FIG. 3B is a simplified graph illustrating efficiency of yellow light conversion versus thickness of a phosphor layer;

FIG. 4A is a simplified cross-sectional view diagram illustrating a lighting apparatus according to an embodiment of the present invention;

FIG. 4B is a simplified top view diagram illustrating a light-conversion layer according to an embodiment of the present invention;

FIG. 5A is a simplified graph illustrating efficiency of yellow light conversion versus thickness of the phosphor layer;

FIG. 5B is a simplified graph illustrating intensity of blue light versus ratio of the clear versus phosphor areas;

FIGS. 6A-6E are simplified top view diagrams illustrating alternative patterns of the light-conversion layer according to embodiments of the present invention;

FIG. 7 is a simplified cross-sectional view diagram illustrating a lighting apparatus 700 according to another embodiment of the present invention;

FIG. 8 is a simplified cross-sectional view diagram illustrating a lighting apparatus 800 according to yet another embodiment of the present invention;

FIG. 9A is a simplified flow diagram illustrating a method for forming a lighting apparatus according to an embodiment of the present invention;

FIG. 9B is a simplified flow diagram illustrating a method for forming a light-conversion layer for a lighting apparatus according to an embodiment of the present invention; and

FIG. 9C is a simplified flow diagram illustrating a method for forming a light-conversion layer for a lighting apparatus according to an alternative embodiment of the present invention.

### DETAILED DESCRIPTION OF THE INVENTION

In embodiments of the invention, various methods are provided for forming a lighting apparatus having a light-conversion layer. The methods allow for independent optimization of light conversion efficiency and proportion of light components having different colors. In a specific application, such a light-conversion layer can be used with a blue LED to produce uniform white light with improved brightness compared to conventional devices. But it will be recognized that the invention has a much broader range of applicability.

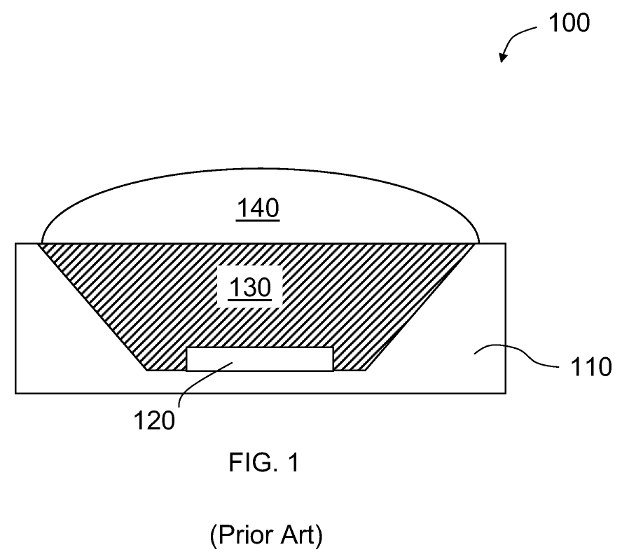

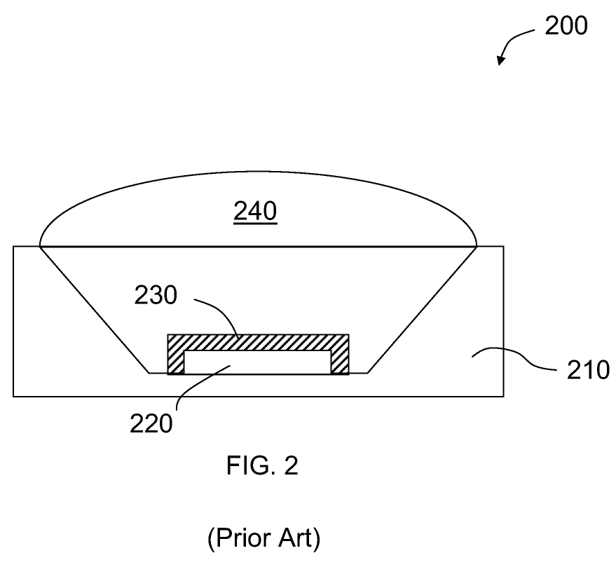

Before embodiments of the present invention are described in detail below, certain limitations of conventional white light LED devices are first analyzed. Two such conventional light emitting devices that incorporate phosphors are illustrated in FIGS. 1 and 2. FIG. 1 shows a schematic diagram of a light emitting device 100 having an LED 120 mounted on a substrate 110. As shown in FIG. 1, LED 120 is disposed at the bottom of a cavity in substrate 110. LED 120 is encapsulated by a layer of a phosphor-containing material 130, which substantially fills the cavity. A lens 140 is provided on top of phosphor-containing layer 130.

FIG. 2 shows a schematic diagram of another conventional light emitting device 200 having an LED 220 mounted on a substrate 210. LED 220 is encapsulated by a conformal phosphor-containing layer 230. As opposed to the light emitting device 100, in the light emitting device 200 the substrate cavity is not filled with phosphor-containing material.

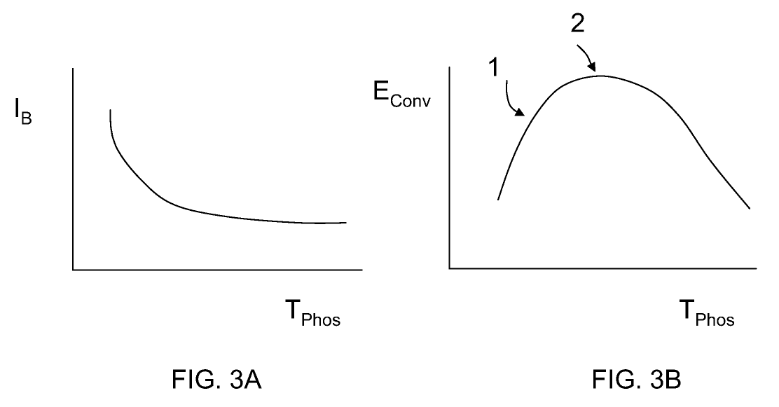

Although finding increasingly wider applications, these conventional devices suffer from many limitations. For example, it is difficult to optimize the LED-phosphor system to obtain desired brightness. In a conventional LED-based device, all light emitted by the LED die must traverse the phosphor layer. Some of the blue light passes through the phosphor unabsorbed, whereas some of the blue light is absorbed by the phosphor and reemitted as yellow light. In order to produce the desired white light, a correct mixture of blue light and yellow light to is required. This requirement places a limitation on the thickness of the phosphor layer, since the fraction of light converted in the phosphor is thickness dependent. This limitation is further illustrated in FIGS. 3A and 3B.

FIG. 3A is a simplified diagram illustrating the relationship between the intensity of blue light (I_{B}) versus the thickness of a phosphor layer (T_{Phos}) for a yellow phosphor layer that absorbs blue light and emits yellow light. As shown in FIG. 3A, the intensity of blue light passing through a phosphor layer follows a substantially exponential absorption curve. That is, as the thickness of the phosphor layer increases, more blue light is absorbed and the intensity of blue light that passes through becomes lower. In the meantime, some of the absorbed blue light is converted to yellow light by the phosphor. In a white light source, the blue light that passes through the phosphor layer balances the yellow light emitted by the phosphor such that an acceptable “white” light is produced. (“White light” as used herein can vary as to color temperature.) This balance requirement largely determines the thickness and amount of phosphor in the phosphor layer in conventional devices. However, this combination of thickness and loading is often not optimal in producing high efficiency or high brightness, as demonstrated below.

FIG. 3B is a simplified diagram illustrating the efficiency of yellow light conversion (E_{Conv}) versus the thickness of the phosphor layer (T_{Phos}). The conversion efficiency reflects a ratio of the number of re-emitted yellow photons to the number of incoming blue photons. As shown in FIG. 3B, the efficiency of yellow light conversion substantially follows a skewed bell-like curve. That is, the intensity of re-emitted yellow light for a fixed intensity of incoming blue light tends to increase with the thickness of the phosphor layer, reaching a plateau near point “2”; beyond point 2, intensity of the yellow light decreases with further increase in phosphor layer thickness. In other words, to achieve maximum brightness for a given blue LED, the phosphor thickness should be at or near point 2. However, this thickness does not necessarily produce the desirable white light, because the amount of blue light passing through may not balance the yellow light due to the fall-off of blue light intensity I_{B} with phosphor thickness T_{Phos} as shown in FIG. 3A. At the optimum thickness near point 2, the final color generally appears yellow rather than white. Therefore, conventional LED devices often limit the phosphor layer thickness to near point “1” in FIG. 3B in order to provide the required ratio of blue to yellow light so that the light appears white. As a result, the brightness of conventional LED devices often is limited.

In embodiments of the present invention, various methods are provided for lighting apparatus having a light-conversion layer that allows for independent optimization of light conversion efficiency and proportion of light components having different colors. In the examples described below, such a light-conversion layer is used with a blue LED to produce substantially uniform white light with improved brightness as compared to conventional devices.

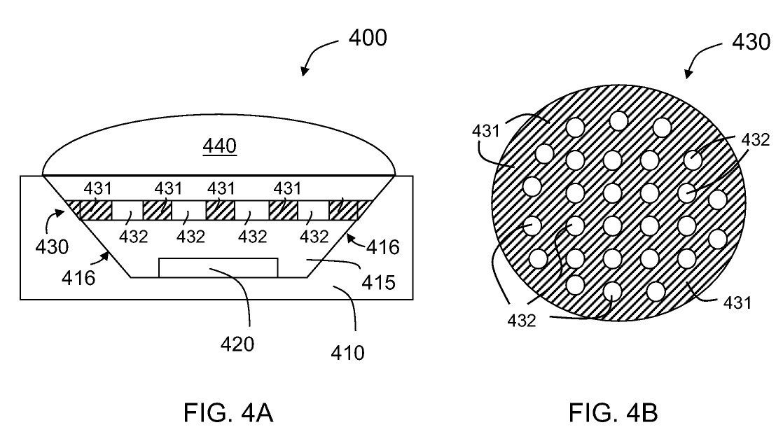

FIG. 4A is a simplified cross-sectional view diagram illustrating a lighting apparatus 400 according to an embodiment of the present invention. As shown, lighting apparatus 400 includes a substrate 410, which has a recess 415 with tapered sidewalls 416 so that the recess is shaped like a section of an inverted cone. A light-emitting diode (LED) 420 is disposed in a bottom portion of recess 415. Lighting apparatus 400 also includes a light-conversion layer 430 overlying LED 420. In various embodiments, light conversion layer 430 might or might not be in contact with LED 420. In a specific embodiment, light-conversion layer 430 includes a phosphor material. In some embodiments, an auxiliary member 440 is disposed over the top opening of recess 415. Auxiliary member 440 is optional and can be, for example, an optical lens for focusing the light emitted from device 400. Auxiliary member 440 can also serve as a protective capping layer.

As shown FIG. 4A, light-conversion layer 430 includes regions 431 of a first type and regions 432 of a second type. Regions 431 and regions 432 are substantially non-overlapping. That is, light emitting from LED 420 can pass through light-conversion layer 430 by traversing either one of regions 431 or one of regions 432. The rest of recess 415 can be filled with a transparent material, such as a material containing resin, gel, or silicone. Any material that is substantially transparent to the light wavelengths of interest can be used. In some embodiments, the rest of recess 415 is filled with a thermally insulating material. Various materials, including polymers, ceramics and glasses, can be used as the thermal insulating material. In one embodiment, the thermal insulating material is a polyimide. In another embodiment, the thermal insulating material is a solvent-soluble thermoplastic polyimide.

In an embodiment, regions 431 include a phosphor-containing material (as suggested by hatching in the drawings), and regions 432 do not have phosphor-containing material. In other words, colored light from LED 420 passing through regions 431 may be converted to a different color through absorption and re-emission. In contrast, regions 432 are substantially transparent to the light from LED 420, and light passing though regions 432 substantially retains its original color. As a result, lighting apparatus 400 produces light with a combination of both colors.

In a specific embodiment, the thickness of regions 431 and the concentration of phosphor therein is selected such that conversion efficiency is maximized. In the meantime, regions 432 can be holes formed in the light-conversion layer that allow blue light to escape directly. Consequently, the blue light used to make a good white color is obtained partly from open regions 432 and partly from blue light that is not absorbed in the phosphor regions 431. This allows for much improved color control, as the number and size of open regions 432 can be varied independently of the thickness of light-conversion layer 430.

FIG. 4B is a simplified top view diagram further illustrating light-conversion layer 430 according to an embodiment of the present invention. As shown, light-conversion layer 430 includes non-overlapping regions 431 and regions 432. In this example, regions 431 include a phosphor-containing material, and regions 432 are substantially free of phosphor-containing material. For example, regions 432 can be holes in light-conversion layer 430. Alternatively, regions 432 may include a transparent material such as epoxy or silicone.

In conjunction with an LED that emits light of a first color, regions 431 convert light of the first color to light of a second color, whereas regions 432 are substantially transparent to light of the first color. As a result, light-conversion layer 430 is capable of receiving light of a first color and producing light that is a combination of the first color and the second color. As an example, by selecting suitable patterns of the two regions, light-conversion layer 430 can be configured to provide substantially uniform light of a third color.

In some embodiments, device 400 can be used for producing a substantially uniform white light. In a specific embodiment, light source 420 is a blue LED, and regions 431 contain yellow phosphor. A combination of blue light from non-phosphor regions 432 and yellow and blue light from phosphor regions 431 can be used to produce white light. The yellow light intensity can be maximized by selecting a desired thickness of phosphor regions 431, as indicated in FIG. 3B. The balance of yellow and blue light to produce white light is created by additional blue light that passes through non-phosphor regions 432, and the size and number of regions 432 can be adjusted for the desired color balance without affecting the conversion efficiency of phosphor regions 431. This design allows for much improved color control.

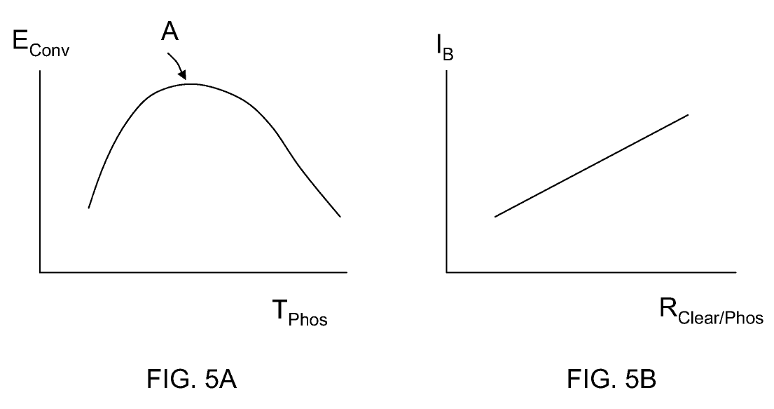

Accordingly, embodiments of the invention provides methods for optimization of the light-conversion layer to provide improved brightness. The light conversion efficiency is described above with reference to FIG. 3B, which is reproduced in FIG. 5A. As shown, maximum yellow light conversion efficiency can be obtained by selecting thickness at point “A” in FIG. 5A. Then the relative amount of the blue light and yellow light can be adjusted by varying the ratio of respective areas of the non-phosphor (clear) regions to the phosphor regions (R_{Clear/Phos}) e.g., by varying the size and/or number of regions 432. As shown in FIG. 5B, the blue light intensity I_{B} increases with R_{Clear/Phos}. In other words, the ratio of yellow light to blue light can be determined independently of the thickness of the yellow phosphor layer. Thus, yellow light conversion efficiency and color ratio can be optimized independently. Furthermore, both yellow light and blue light can be provided at high intensity. As a result, the brightness of the output light can be improved.

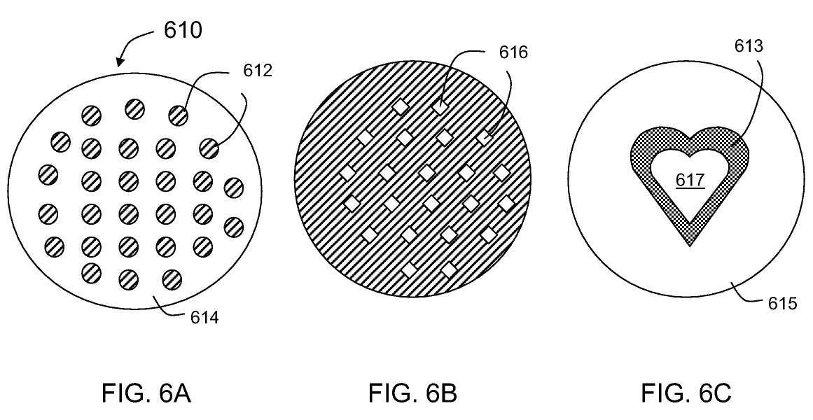

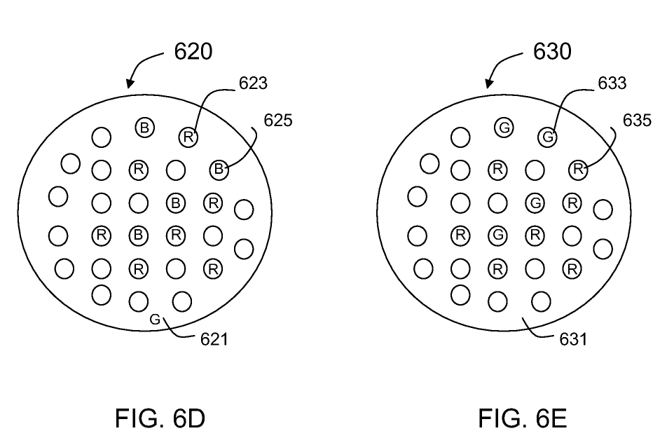

In specific embodiments, a uniform pattern of yellow phosphor regions and non-phosphor regions can be used to produce substantially uniform white light. In an example, a dense pattern of small regions may be used to provide uniformity. Each of the regions may also have different shapes. Some examples are shown in FIGS. 4B and 6A-6C. In FIG. 4B, holes are formed in phosphor layer 430, leaving phosphor regions 431 interspersed with holes 432 that do not contain phosphor. Alternatively, holes can be filled with transparent non-phosphor materials such as resin or silicone. In FIG. 6A, light-conversion layer 610 is formed using transparent non-phosphor materials such as resin or silicone. Holes 612 are formed in layer 610 and filled with a phosphor-containing material. Thus, regions 614 are examples of non-phosphor regions while regions 612 are phosphor regions. Additionally, the shapes of phosphor-containing regions or non-phosphor regions need not be circular. Merely as an example, FIG. 6B shows a pattern of diamond-shaped regions 616, which can be either phosphor or non-phosphor regions. Furthermore, the size and density of the regions can also be varied for different applications. In other examples, a non-uniform pattern may be used to compensate for irregularities in the system (e.g., non-uniform light distribution from the LED). In still other examples where custom-designed light patterns are desired instead of uniform light, the regions can be arranged to produce such patterns. An example is shown in FIG. 6C, where a heart-shaped region 613 can contain red phosphor while surrounding region 615 and interior region 617 are substantially free of phosphor.

The invention is not limited to a single type of phosphor-containing region. FIG. 6D shows another example of a light-conversion layer 620 having one type of phosphor 621, e.g., a green phosphor (G), as the base material and including holes filled with different types of phosphors 623 and 625, e.g., red (R) and blue (B) phosphors. The pattern of the different materials can be varied to obtain a desired color balance. Such a light-conversion layer can be used with a UV LED in a lighting apparatus to produce white or colored light depending on the pattern of phosphors. FIG. 6E shows yet another example of a light-conversion layer 630 having region 633 of green (G) phosphors and region 635 of red (R) phosphors included in a transparent base material 631. In another embodiment, each region can have a mixture of different phosphors. For example, certain regions can have mixtures of red, green, and blue (RGB) phosphors. In a specific application, light conversion layers with regions containing different types of phosphors can be used with various LEDs to produce white light or light containing desired colors or color patterns. In these examples, the relative area, thickness and phosphor concentrations of the various regions can be separately controlled to optimize brightness and color balance for a particular application.

In a specific embodiment, a 50% increase in the intensity of white light has been achieved using a light-conversion layer similar to the examples described above. In this embodiment, the light-conversion layer has approximately 90% of its area devoted to yellow phosphor regions and approximately 10% to non-phosphor silicone regions. The yellow phosphor regions contain YAG:Ce³⁺ and have a thickness of approximately 500 um. The patterns are similar to light-conversion layer 430 shown in FIG. 4B, having a plurality of holes. In this particular embodiment, the holes occupy approximately 10% of the total area of the light-conversion layer.

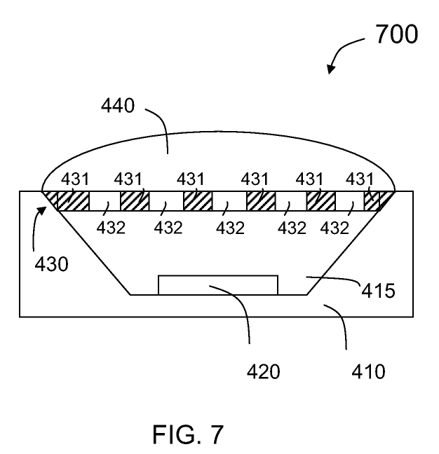

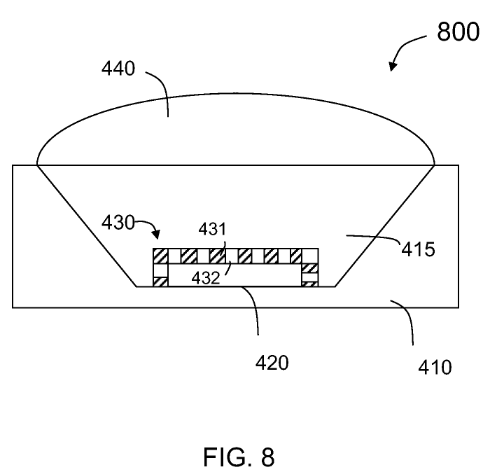

Although a specific embodiment is shown for lighting apparatus 400 in FIGS. 4A and 4B, there can be many alternatives, modifications, and variations. Some of the variations are shown in FIGS. 7 and 8. FIG. 7 is a simplified diagram illustrating a lighting device 700 according to another embodiment of the invention. As shown, device 700 is similar to lighting device 400 in FIG. 4A, and the same numerals are used to designate similar components in each device. For example, light-conversion layer 430 has phosphor regions 431 and non-phosphor regions 432. In FIG. 4A, light-conversion layer 430 is shown to be spaced apart from LED 420 and lens 440. In contrast, FIG. 7 shows light-conversion layer 430 in physical contact with lens 440.

Similarly, FIG. 8 is a simplified diagram illustrating a lighting device 800 according to another embodiment of the invention. In FIG. 8, light-conversion layer 430 is in physical contact with light-emitting diode 420. In the configurations of FIGS. 7 and 8, light-conversion layer 430 can be bonded directly to lens 440 or LED 420 with a bonding agent such as an adhesive. Of course, one skilled in the art can envision other variations.

In alternative embodiments of the invention, other combinations of colored light sources and phosphor or other wave-shifting materials can be used to form lighting devices of different colors. For example, complementary colors such as red and cyan or green and magenta can be used with the invention to form white light sources. Furthermore, light sources outside the visible spectrum, such as UV light sources, can also be used with the invention. The wavelengths emitted by various available LEDs can extend over a wide spectrum, including both visible and invisible light, depending on the type of the LED. The wavelengths of common LEDs are generally in a range of about 200 nm-2000 nm, namely from the infrared to the ultraviolet.

It will also be appreciated that certain features have been omitted from FIGS. 4, 7, and 8 for clarity. For example, the sidewalls of recess (or cavity) 415 and substrate 410 can be part of a larger package that provides electrical connections (not shown) to LED 420. In some embodiments, recess 415 is defined into an existing material (e.g., by etching) to form sidewalls 416 that define recess 415. In other embodiments, substrate 410 is a discrete layer, and recess 415 can be created by bonding one or more layers above substrate 410. In still other embodiments, an LED could be mounted on a flat substrate without a recess.

It will be appreciated that the lighting apparatus and light-conversion layers described herein are illustrative and that variations and modifications are possible. For example, the regions in the light-conversion layers can have any shape, any number, and any density desired. Moreover, light-conversion layers need not be circular when viewed from above (or below). In general, the shape of the light conversion layer can conform to the shape of the recess or other packaging.

In the specific examples described above, phosphors are used for LED-based light sources. Common phosphors for these purposes include yttrium aluminum garnet (YAG) materials, terbium aluminum garnet (TAG) materials, ZnSeS+ materials, and silicon aluminum oxynitride (SiAlON) materials (such as α-SiAlON), etc. According to embodiments of the present invention, however, any material that converts wavelength of incident light can be used. Additionally, in a light-conversion layer, the phosphor regions need not all have the same phosphor material; different color phosphor materials may be used to fill various phosphor regions, as in the examples in FIGS. 6D and 6E above.

In other embodiments, other wave-shifting material can be substituted for phosphor materials. As used herein, a “wave-shifting” material includes any material that, when struck by light of a first wavelength, produces light of a second wavelength. Examples of wave-shifting materials include phosphor-containing materials, fluorescent materials, and the like. A “wave-shifting region” can be any region that contains a significant concentration of a wave-shifting material (e.g., a phosphor material dispersed in a host matrix), while a “non-wave-shifting region” is substantially free of wave-shifting material. The latter may contain any material that is substantially transparent to light of the first wavelength.

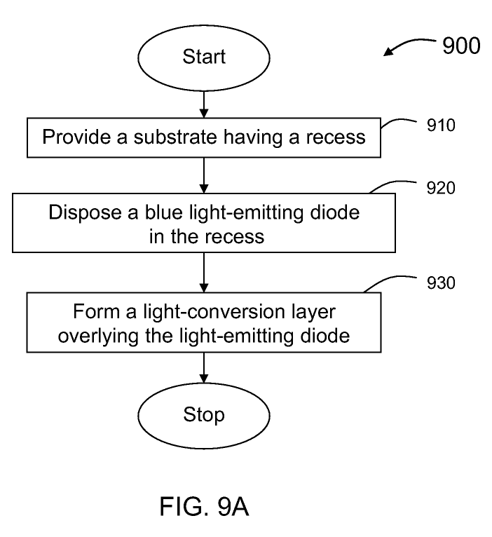

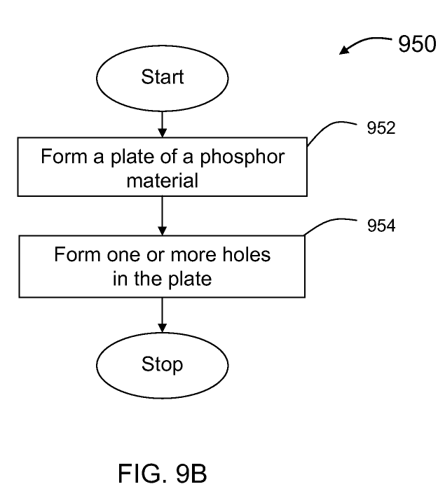

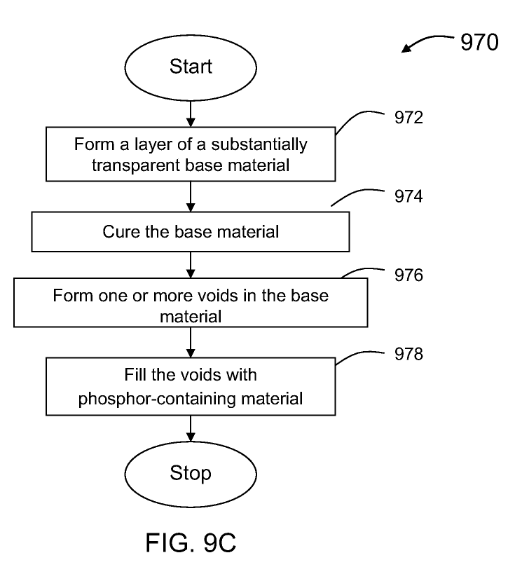

According to another embodiment of the present invention, a method for making a lighting apparatus is provided. FIG. 9A is a simplified flow diagram illustrating a method 900 for making a lighting apparatus having a light-conversion layer as described above. At step 910, a substrate having a recess in a front side is provided. The substrate and recess can be formed using known methods. For example, in some embodiments, the recess is defined into an existing material to form the sidewalls and the substrate, e.g., by etching the substrate material. In other embodiments, the substrate is a discrete layer, and the cavity can be defined into one or more layers bonded above the substrate. In some embodiments, the recess has tapered sidewalls, e.g., as shown in FIG. 4A. Other examples of substrates are described in U.S. patent application Ser. No. 11/036,559, filed on Jan. 13, 2005 and entitled “Light Emitting Device with a Thermal Insulating and Refractive Index Matching Material,” which is commonly owned and incorporated by reference herein.

At step 920, a light-emitting diode is disposed in the recess. For example, the LED can be bonded or soldered to a bottom portion of the recess. The LED itself can be of conventional design and can be fabricated using known techniques. The LED can be obtained in various ways, including in-house fabrication, acquisition from a manufacturer, or the like.

At step 930, a light-conversion layer is formed and is disposed to overly the light-emitting diode. The light-conversion layer has advantageously one or more wave-shifting regions and one or more non-wave-shifting regions. Furthermore, the light-conversion layer is configured to provide substantially uniform white light. Examples of light-conversion layers are described above with reference to FIGS. 4A through 8. Depending on the embodiments, the light-conversion layer can be formed using different processes, as described below.

In a specific embodiment, the method for forming the light-conversion layer includes forming a phosphor-containing layer and then forming one or more holes in the phosphor-containing layer. This method is illustrated by flow chart 950 in FIG. 9B, and examples of light-conversion layers formed according to method 950 are described above in connection with FIGS. 4B and 6B.

Referring to FIG. 9B, at step 952, a plate (i.e., a substantially uniformly thick layer) of phosphor material (or other wave-shifting material) is formed. Conventional techniques can be used. Currently available phosphors are often based on oxide or sulfide host lattices including certain rare earth ions. Some examples of phosphor materials are described above. According to embodiments of the present invention, the thickness of the plate is selected so as to provide a predetermined amount of converted light. For example, the thickness can be chosen for maximum light conversion efficiency, as shown in FIG. 5A.

At step 954, one or more holes are formed in the plate (see, e.g., regions 432 in FIGS. 4A and 4B). The holes allow light from the LED to pass through, whereas the phosphor regions convert at least some of the light from an LED to a different color; for example, blue light from an LED can be converted to yellow light through absorption and re-emission. For white light applications, the pattern of the holes can be chosen to provide the desired ratio of yellow and blue light and the desired uniformity of the light output from the lighting device. In some embodiments, the holes in the plate can be filled with a base material that is substantially transparent to the light emitted by the LED. Thus, a non-phosphor region (or other non-wave-shifting region) can be substantially free of material or can contain any material that is substantially transparent to the LED light.

In various embodiments, the light-conversion layer can be formed directly on the LED as shown in FIG. 8, or attached to the bottom of the lens as shown in FIG. 7, or disposed away from either the LED or the lens as shown in FIG. 4A. In the embodiment of FIG. 4A, the light-conversion layer can be spaced apart from the LED and the lens, e.g., by a transparent base material such as resin or silicone. The term “overlying” is to be understood as encompassing any and all such possibilities.

FIG. 9C is a simplified flow chart illustrating a method 970 for forming the light-conversion layer according to another embodiment of the present invention. First, at step 972, a layer is formed using a base material that is substantially transparent to the light emitted from the light-emitting diode. The layer of base material is then cured at step 974. Next, one or more voids (holes) are formed in the base material at step 976. At step 978, the one or more voids are filled with a phosphor-containing material (or other wave-shifting material).

An example of light-conversion layer formed using method 970 is described above in connection with FIG. 6A. A plate 610 of transparent base material has one or more holes 612 that are filled with a phosphor-containing material. The base material can be, e.g., a gel of silicone, an epoxy material, or other suitable material that is transparent to light emitted from the LED. Plate 610 can be disposed in a lighting device similar to device 400 in FIG. 4A. Here, many of the considerations associated with method 950 are applicable in method 970. For example, the ratio of areas of phosphor regions to non-phosphor-regions can be selected so as to produce light of a desired color, and the thickness of the phosphor regions can be chosen for high light conversion efficiency. Additionally, the pattern of the phosphor and non-phosphor regions can be designed to provide substantially uniform light output.

In an alternative embodiment, method 970 for forming the light-conversion layer can be used to fill the recess in the LED of the lighting apparatus in FIG. 4A and cover the LED with a transparent base material. One or more holes are formed in the base material, and the holes are filled with a phosphor-containing material. In this embodiments, the holes need not extend all the way through the thickness of the base material; instead, depth of the holes can be selected so as to maximize light conversion efficiency.

The above processes provide methods for manufacturing a lighting apparatus according to embodiments of the present invention. The methods allow for separate optimization of light-conversion efficiency and color mixing. As shown, the methods use a combination of steps including forming a light-conversion layer having phosphor-containing regions and non-phosphor regions configured to provide bright and uniform light. Other alternatives can also be provided where steps are added, one or more steps are removed, or one or more steps are provided in a different sequence without departing from the scope of the claims herein. Further details of the present method can be found throughout the present specification.

While certain embodiments of the invention have been illustrated and described, those skilled in the art with access to the present teachings will recognize that the invention is not limited to these embodiments only. Numerous modifications, changes, variations, substitutions, and equivalents will be apparent to those skilled in the art. Accordingly, it is to be understood that the invention is intended to cover all variations, modifications, and equivalents within the scope of the following claims.

What is claimed is:

1. A lighting apparatus, comprising:
a light-emitting diode configured to emit light of a first color; and
a light-conversion layer overlying the light-emitting diode, the light-conversion layer including at least one first region that is substantially transparent to light of the first color and at least one second region that is configured to convert light of the first color to light of a second color.

2. The apparatus of claim 1 wherein the at least one second region comprises a phosphor-containing material.

3. The apparatus of claim 1 wherein the at least one first region comprises silicone or epoxy.

4. The apparatus of claim 1 wherein the at least one first region comprises a void in the light-conversion layer.

5. The apparatus of claim 1 wherein the at least one first region and at least one second region are arranged such that the lighting apparatus provides substantially uniform light of a third color.

6. The apparatus of claim 5 wherein the third color is white.

7. The apparatus of claim 6 wherein the first color is blue and the second color is yellow.

8. The apparatus of claim 5 wherein a ratio of areas of the at least one first region to the at least one second region is selected for providing light of the third color.

9. The apparatus of claim 1 wherein a thickness of the at least one second region is selected to maximize brightness of the light of the second color.

10. The apparatus of claim 1 wherein the light-conversion layer further comprises at least one third region that is configured to convert light of the first color to light of a third color.

11. The apparatus of claim 1 wherein the light-conversion layer is spaced apart from the light-emitting diode.

12. The apparatus of claim 1 wherein the light-conversion layer is in contact with the light-emitting diode.

13. The apparatus of claim 1 further comprising a lens overlying light-conversion layer, wherein the light-conversion layer is in contact with the lens.

14. The apparatus of claim 1 further comprising a substrate having a recess, wherein the light-emitting diode and the light conversion layer are disposed within the recess.

15. A method for making a lighting apparatus, the method comprising:
obtaining a light-emitting diode configured to emit light of a first color; and
forming a light-conversion layer overlying the light-emitting diode, the light-conversion layer having a plurality of non-overlapping regions including at least one wave-shifting region and at least one non-wave-shifting region,
wherein the at least one wave-shifting region is configured to convert at least a portion of incident light of the first color to light of a second color and the at least one non-wave-shifting region is substantially transparent to light of the first color,
wherein the light-conversion layer is configured to provide substantially uniform light of a third color.

16. The method of claim 15 wherein forming the light-conversion layer comprises:
forming a layer using a base material that is substantially transparent to light of the first color;
curing the layer of base material;
forming one or more voids in the base material; and
filling the one or more voids with a wave-shifting material.

17. The method of claim 16 wherein providing the light-emitting diode comprises:
providing a substrate having a recess; and
disposing the light-emitting diode in the recess,
wherein the layer of base material substantially fills the recess in the substrate.

18. The method of claim 16 wherein the base material includes a gel of silicone or an epoxy material.

19. The method of claim 15 wherein forming the light-conversion layer comprises:
forming a plate of a wave-shifting material, a thickness of the plate being selected for providing a predetermined conversion efficiency for producing light of the second color; and
forming one or more holes in the plate.

20. The method of claim 19 further comprising filling the holes with a base material that is substantially transparent to light of the first color.

21. The method of claim 15 wherein a ratio of areas of wave-shifting regions to non-wave-shifting regions is selected for providing substantially uniform white light.

22. The method of claim 15 wherein forming the light-conversion layer comprises:
providing a lens;
forming the light-conversion layer on a back surface of the lens; and
disposing the lens over the light-emitting diode.

23. The method of claim 15 wherein the light-conversion layer is formed on a top surface of the light-emitting diode.

24. A light conversion device, comprising:
a light-conversion layer having a plurality of non-overlapping regions including at least one wave-shifting region and at least one non-wave-shifting region,
wherein the at least one wave-shifting region is configured to convert light of a first color to light of a second color and the at least one non-wave-shifting region is substantially transparent to light of the first color.

25. The light conversion device of claim 24 wherein a thickness of the wave-shifting region is selected to maximize conversion efficiency for light of the second color.

26. The light conversion device of claim 24 wherein a ratio of areas of the wave-shifting region to the non-wave-shifting region is selected for providing light of a third color.

27. The light conversion device of claim 24 wherein a pattern of the wave-shifting region and the non-wave-shifting region is selected for providing substantially uniform light of the third color.

28. The light conversion device of claim 26 wherein the third color is white.

29. The light conversion device of claim 24 wherein the first color is blue and the second color is yellow.

30. The light conversion device of claim 24 wherein the at least one non-wave-shifting region comprises a void in the light-conversion layer.

31. A light conversion device, comprising:
a light-conversion layer having a plurality of non-overlapping regions including at least one region of a first type and at least one region of a second type,
wherein the at least one region of the first type is configured to convert incident light of a first color to light of a second color and the at least one region of the second type is configured to convert incident light of the first color to light of a third color that is different from the second color.

32. The light conversion device of claim 31 wherein the light-conversion layer further includes at least one region of a third type, wherein the at least one region of the third type is substantially transparent to incident light of the first color.

33. The light conversion device of claim 31 wherein a thickness of the at least one region of the first type is selected to maximize a conversion efficiency for converting incident light of the first color to light of the second color and wherein a thickness of the at least one region of the second type is selected to maximize a conversion efficiency for converting incident light of the first color to light of the third color.
